(19) United States
(12) Patent Application Publication
(10) Pub. No.: US 2021/0303099 A1
(43) Pub. Date: Sep. 30, 2021

(54) PROXIMITY SENSING

(71) Applicant: Elliptic Laboratories AS, Oslo (NO)

(72) Inventors: Guenael Thomas STRUTT, San Francisco, CA (US); Espen KLOVNING, Strømmen (NO)

(21) Appl. No.: 17/261,844

(22) PCT Filed: Sep. 10, 2019
(86) PCT No.: PCT/NO2019/050178

§ 371 Date: Jan. 20, 2021

Related U.S. Application Data
(60) Provisional application No. 62/730,200, filed on Sep. 12, 2018.

(30) Foreign Application Priority Data
Oct. 12, 2018 (NO) 20181316

(51) Int. Cl. G06F 3/041; G06F 3/01; G06F 1/3231; G06F 1/16

(52) U.S. Cl. CPC G06F 3/0416; G06F 1/1626; G06F 1/3231; G06F 3/011

(57) ABSTRACT

Present teachings relate to a method for controlling an electronic device comprising a touch-sensitive surface and a proximity sensor, comprising the steps of:—Changing the device from a screen-on state to a near state in response to a near event being detected by the proximity sensor and the near event occurs when an input object is determined to be in proximity of the electronic device by the proximity sensor;—While the device is in the near state, processing a first category touch event, and in response to the processing of the first category touch event, performing at least one function on the electronic device;—While the device is in the near state, ignoring a second category touch event, wherein the second category touch event is distinct from the first category touch event.

### TECHNICAL FIELD

Present teachings relate to proximity sensing for an electronic device.

### BACKGROUND ART

Most mobile devices, especially mobile phones or smartphones, have a proximity sensor that is typically placed near the top of the screen of the device, or close to the earpiece. The main function of such a proximity sensor is to detect when the user has positioned the device close to the ear during an ongoing phone call, in which case the touchscreen of the mobile device is disabled or switched off to prevent false touch events due to contact of the ear or other body part of the user with the screen of the mobile device. Since the touch screen is not normally used while the user has placed a call and has positioned the device close to their head or next to their ear, the touch screen controller can either be switched off or may enter a low-power mode to save power. Additionally, the screen lighting of the device is also normally switched off to save power.

Since such a proximity detection system normally works by detecting an object near the top of the phone, for example during an ongoing call, there can be conditions where the screen is turned off by the proximity detection system when it is not actually desired, such as when fingers approach the top of the phone. As can be appreciated, such an event with a false positive can hinder proper control of the device and affect user experience. In WO2012/112181 this problem is solved by using the orientation of the device in addition to the proximity sensor to verify if the user is holding the device toward the ear in a vertical orientation. This, however, may introduce false positives if the user holds the phone in an unconventional way.

### SUMMARY

At least some problems inherent to the prior-art will be shown solved by the features of the accompanying independent claims.

Viewed from a first perspective, there can be provided a method for controlling an electronic device such that false positive detections for a proximity event on the electronic device are reduced.

Viewed from another perspective, there can be provided a method for preventing controlling the touchscreen of a mobile device for allowing a swipe down event on the touch screen to be executed.

Viewed from a perspective, there can be provided a method for controlling an electronic device, the device comprising a touch-sensitive surface and a proximity sensor, the proximity sensor having a field-of-view, the method comprising the steps of:
Changing the device from a screen-on state to a near state in response to a near event being detected by the proximity sensor, wherein the screen-on state is a state in which user inputs are accepted through the touch-sensitive surface; and the near event occurs when an input object is determined to be in proximity of the electronic device by the proximity sensor;
While the device is in the near state, processing at least a first category touch events, and in response to the processing of the first category touch events performing at least one function on the electronic device; and
While the device is in the near state, ignoring at least a second category touch events, wherein the second category touch events are distinct from the first category touch events.

By saying that the input object is determined to be in proximity of the electronic device, it is meant that the input object is detected by the proximity sensor to be present within the field-of-view (“FoV”) of the proximity sensor. For example, the input object is determined to be in proximity of the electronic device when the input object arrives within a first predetermined distance of the proximity sensor.

Viewed from another perspective, there can be provided a method for controlling an electronic device, the device comprising a touch-sensitive surface and a proximity sensor, the proximity sensor having a field-of-view, the method comprising the steps of:
Changing the device from a screen-on state to a near state in response to a near event being detected by the proximity sensor, wherein the screen-on state is a state in which user inputs are accepted through the touch-sensitive surface; and the near event occurs when an input object is determined to be in proximity of the electronic device by the proximity sensor;
While the device is in the near state, processing at least a first category touch events, and in response to the processing of the first category touch events performing at least one function on the electronic device, wherein the first category touch events include touch inputs occurring within the first portion of the touch-sensitive surface and/or the first category touch events are a first type of touch events;
While the device is in the near state, ignoring at least a second category touch events, wherein the second category touch events include touch inputs occurring in the second portion of the touch-sensitive surface and/or the second category touch events are a second type of touch events; the first portion and the second portion being non-overlapping portions of the touch-sensitive surface.

According to another aspect, the method further includes the steps of:
Waiting for a predetermined time-period in the near state within which period, if no first category touch event is detected, then changing the device to a screen-off state, wherein the screen-off state is a state in which the touch-sensitive surface is either disabled or any inputs received thereof are ignored; and
Changing from the screen-off state to the screen-on state in response to a far event being detected by the proximity sensor, wherein the far event occurs when the input object is determined to no longer be in proximity of the electronic device by the proximity sensor.

By saying that the input object is determined to no longer be in proximity of the electronic device, it is meant that the input object is detected by the proximity sensor to be absent from the FoV of the proximity sensor. For example, the input object is determined to no longer be in proximity of the electronic device when the input object moves beyond a second predetermined distance from the proximity sensor. The first predetermined distance and the second predetermined distance can be equal values, or alternatively they can be different values, for example for implementing hysteresis in changing the states in response to the input object entering and departing the FoV of the proximity sensor. The arriving/departing of the input object in/from the FoV is meant in a relative sense to the electronic device, i.e., by saying e.g., the input object arrives within a first predetermined distance of the proximity sensor covers all scenarios whether it be, the input object moving towards a stationary electronic device, or the electronic device being brought towards a stationary input object, or both the electronic device and the input object moving towards each another.

The magnitude of the first predetermined distance may at least substantially equal to the magnitude of the second predetermined distance, or alternatively the magnitude of the first predetermined distance may different from the magnitude of the second predetermined distance.

Viewed from another perspective, there can be provided an electronic device comprising a touch-sensitive surface and a proximity sensor, the electronic device also comprising a processing unit configured to:
process user input received through the touch-sensitive surface;
process signal received by the proximity sensor, wherein
the electronic device is configured to enter a near state in response to a near event being detected by the proximity sensor; and the screen-on state being a state in which user inputs are accepted through the touch-sensitive surface and processed by the processing unit; and the near event occurs when an input object is determined to be in proximity of the electronic device by the proximity sensor;
process a first category touch event, and based on the processing of the first category touch event performing at least one function on the electronic device; and
ignore a second category touch event, wherein the second category touch event is distinct from the first category touch event.

Viewed from yet another perspective, an electronic device can be provided, the electronic device comprising a touch-sensitive surface and a proximity sensor, the electronic device also comprising a processing unit configured to:
process user input received through the touch-sensitive surface; and
process signal received by the proximity sensor, wherein
   the electronic device is configured to enter a near state in response to a near event being detected by the proximity sensor; and the screen-on state being a state in which user inputs are accepted through the touch-sensitive surface and processed by the processing unit; and the near event occurs when an input object is determined to be in proximity of the electronic device by the proximity sensor;
process a first category touch event, and based on the processing of the first category touch event performing at least one function on the electronic device, wherein the first category touch events include touch inputs occurring within the first portion of the touch-sensitive surface and/or the first category touch events are a first type of touch events; and
ignore a second category touch event, wherein the second category touch event includes a touch input occurring in the second portion of the touch-sensitive surface and/or the second category touch events are a second type of touch events, wherein
   the first portion and the second portion are non-overlapping portions of the touch-sensitive surface.

According to yet another aspect, the processing unit is configured to ignore the second category touch event by disabling the second portion of the touch-sensitive surface, or alternatively, the processing unit is configured to ignore the second category touch event by disregarding touch inputs received through the second portion of the touch-sensitive surface.

The first type of touch events may include any one or any combination of tap, double-tap, hold or swipe events.

The second type of touch events may include any one or any combination of tap, double-tap, hold or swipe events.

According to an aspect, the second type of touch events is distinct from the first type of touch events, so that the first type of touch events is processed, while the second is ignored. For example, a touch event of type ‘swipe’ cannot be used as a first type and also as a second type; it can only be used either as a first type or as a second type.

The electronic device may also comprise a display. The display may be used for user interaction with the device, and for displaying characters, pictures, or videos, etc. It will be understood that in certain cases such as for a TFT LCD display, the display also comprises a backlight, while other kinds of display may be self-illuminated. According to another aspect, the display is turned-off or switched-off when the electronic device enters the near state, while the touchscreen sensor or touch-sensitive surface in still active for detecting first category touch events. Alternatively, in some cases the display is switched-off when the electronic device enters the near state while the touchscreen sensor in still active for detecting first category touch events. In other cases, the display is kept on for a predetermined time-period after the electronic device changes to or enters the near state. After the expiry of the time-period, if the electronic device is still in the near state, the display is switched-off, while the touchscreen sensor in still kept active for detecting first category touch events. It will be appreciated that based on the use case of the electronic device, this can save power whilst allowing for detection of touch events for a longer period of time.

The proximity sensor may be infrared (“IR”) detection based, or it may be acoustic detection based. Alternatively, or in addition, the teachings can also apply to other kinds of proximity detection arrangements such as those based on electric field, light, magnetic field, or capacitive field.

According to an aspect, the proximity detection system may be based on the transmission and receiving of acoustic signals. Accordingly, the proximity detection mode comprises the transmission, reflection, and detection of acoustic, particularly ultrasonic signals.

The proximity sensor may include a plurality of sensors. The proximity sensor may even include a combination of various kinds of proximity detection arrangements. For example, a combination of an IR sensor and an acoustic sensor.

As will be appreciated, an IR-sensor based proximity sensing can be replaced by ultrasound sensing alone or in combination with capacitive sensing. In devices where ultrasound sensing is already implemented for gesture recognition, by using ultrasound sensing in combination with touch sensing, the requirement for a separate IR proximity sensor may be removed. Manufacturing costs may thus be reduced.

An acoustic proximity detection arrangement, or more specifically an ultrasound-sensor based proximity detection arrangement, comprises at least one transmitter and at least one receiver. The transmitter is used for transmitting an ultrasound signal, and the receiver is used for receiving at least some portion of the ultrasound signal being reflected by an object.

The object may be almost any animate or an inanimate object. In some cases, a body part of a user, such as a hand, may be considered an object. In other cases, one or more fingers may be considered an object. Alternatively, inanimate things such as either a stylus or a pen may be considered an object. For the sake for detection or sensing of proximity, an input object can be anything that can trigger the proximity detection system. In most common cases, the head of the user, or ear, or even hair of the user may be considered input objects.

As will be appreciated, the transmitter and receiver may either be different components or alternatively they can be the same transducer that is used in a transmit mode for transmitting the ultrasound signal and then in a receive mode for receiving the reflected ultrasound signal. If the transmitter and receiver are different components, they may be placed in the same location, or they may be installed at different locations on the electronic device. Furthermore, the electronic device may comprise a plurality of transmitters and/or a plurality of receivers. Multiple transmitter-receiver combinations may be used to extract spatial information related to the object and/or surroundings.

According to another aspect, the method may further comprise computing a distance value by the processing of the measured signal, said distance value can be relative to the distance between the input object and the electronic device, or more specifically the proximity sensor.

The processing of the signal or a plurality of signals received by the proximity sensor can be done by a processing unit such as a computer processor. The processing unit may either be the same processor that is used for processing signals received by the touch-sensitive surface, or it may be a separate processor. A usage of the term processing unit in this disclosure thus includes both alternatives, i.e., separate processors and same processor. The processing unit can be any type of computer processor, such as a DSP, an FPGA, or an ASIC.

The range and/or sensitivity, and thus the field-of-view, of the proximity sensing arrangement may either be limited according to component specifications, or it may be statically or dynamically adapted by the processing unit to a certain value according to processing requirements and/or use case of the electronic device. The field-of-view may be encompassing at least partially the first portion of the touch-sensitive surface.

According to another aspect, the method may also comprise transmitting data related to the input object to another electronic module of the electronic device. The input object related data may include one or more of: input object position, distance, speed, estimated trajectory, and projected trajectory. Another electronic module may be a hardware or software module, and may include any one or more of, application programming interface (“API”), and sensor fusion module. For example, data related to either one or any of, distance, speed of movement, position, and gesture type may be transmitted used by the processing unit to estimate the use case of the electronic device.

According to another aspect, the method also comprises receiving data from at least one of the other sensors or modules in the electronic device for improving the robustness of the control of the electronic device. The other sensors or modules may include any one or more of, accelerometer, inertial sensor, IR sensor, or any other sensor or modules related to a sensor fusion module in the electronic device.

As will be appreciated, especially with acoustic sensing a wide field-of-view may be achieved. Accordingly, proximity detection can be performed not only on the screen side of the device, but also from an input object that is located at or towards another side of the electronic device. This can for example be used to determine when the electronic device has been placed on a surface such as a table. The electronic device may thus recognize an on-table use case by processing the signal from the proximity sensor and or other sensors in the electronic device. It may thus be recognized that the electronic device has been placed on such a surface.

The processing of the echo signals may be based on time of flight (“TOF”) measurements between the transmitted ultrasound signal and the corresponding received reflected signal. The processing of the echo signals may also be based on the amplitude of the measured signal, or phase difference between the transmitted signal and the measured signal, or the frequency difference between the transmitted signal and the measured signal, or a combination thereof. The transmitted ultrasound signal may comprise either a single frequency or a plurality of frequencies. In another embodiment, the transmitted ultrasound signal may comprise chirps.

The method steps are preferably implemented using a computing unit such as a computer or a data processor.

Viewed from yet another aspect, the present teachings can also provide a computer software product for implementing any method steps disclosed herein. Accordingly, the present teachings also relate to a computer readable program code having specific capabilities for executing any method steps herein disclosed.

The term electronic device includes any device, mobile or stationary. Accordingly, devices such as mobile phones, smartwatches, tablets, notebook computers, desktop computers, and similar devices fall within the ambit of the term electronic device in this disclosure. Preferably, the electronic device is a mobile phone or a smartphone. The electronic device can be executing any of the method steps disclosed herein. Accordingly, any aspects discussed in context of the method or process also apply to the product aspects in the present teachings.

As can be appreciated, the present teachings can allow original equipment manufacturers (“OEMs”) to save effort used on perfecting the proximity detection system. More specifically, the necessity to have a restricted field-of-view or detection distance can be alleviated.

Example embodiments are described hereinafter with reference to the accompanying drawings.

### BRIEF DESCRIPTION OF DRAWINGS

FIG. 1 shows a perspective front view of an electronic device with a proximity detection system

FIG. 2 shows a perspective side view of an electronic device with a proximity detection system

FIG. 3 shows a state-diagram related to the electronic device

FIG. 4 shows a modified state-diagram related to the electronic device

### DETAILED DESCRIPTION

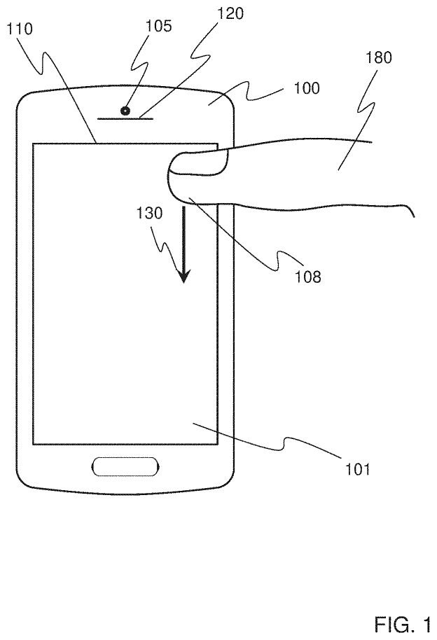

FIG. 1 shows a perspective front view of an electronic device 100 which is shown as a mobile phone. The mobile phone 100 has a screen 101 for displaying and interacting with the device 100. Above the top-edge 110 of the screen 101, an earpiece 120 and a proximity sensor 105 are placed. As will be understood, the earpiece 120 comprises a speaker that is used for outputting acoustic signals such as audio of the caller. In certain phones, the same speaker may also be used for outputting ultrasonic signals, for example for ultrasound-based user interaction. The screen 101 comprises not only a display for displaying pictures and videos, but also a touchscreen sensor for touch based user interaction. The proximity sensor 105 is usually infrared (“IR”) detection based, but it can also be an acoustic-detection based sensor, or another type of sensor suitable for proximity detection. FIG. 1 also shows a finger 180 of a user interacting with the device 100. The tip 108 of the finger 180 is close to the top-edge 110 of the screen 101. One of the possible interactions close the top edge 110 of the screen 101 is a pull-down swipe, which is shown with an arrow 130 indicating the motion of the fingertip 108 while it is in contact with the screen 101. For performing a pull-down swipe, the user will typically place his/her fingertip 101 substantially close to the top-edge 110 and move the fingertip 108 in the direction of the arrow 130 whilst the fingertip remaining in contact with the surface of the screen 101. When the touchscreen controller, connected to the touchscreen sensor, detects a pull-down event resulting from a pull-down swipe 130, it usually sends a signal to a digital processor that performs a certain task. This task can for example be pulling down or displaying of the notification menu on the screen 101.

Usually the proximity sensor 105 does not interfere with the user interaction, however in certain conditions, such as while in-call, the proximity sensor 105 is actively detecting for occurrence of a near event. A near event corresponds to a condition when an object comes within a certain predetermined distance of the proximity sensor 105 within its field of view (“FoV”). The FoV of a proximity sensor 105 is a three-dimensional envelope or space around the sensor 105 within which the sensor 105 can reliably detect a proximity event. Detection of a near event is required, for example, to be able to switch off the touchscreen and display (or screen 101) of the device 100 such that undesired touchscreen operation may be prevented. Such undesired touchscreen operation could otherwise occur when the user has placed the earpiece 120 close to his/her ear, in which condition, if the touchscreen were not disabled and the ear of the user touched the screen 101. Detection of a near event by using the proximity sensor 105 causes the touchscreen to be disabled such that undesired touchscreen operation is prevented.

When proximity sensing with the sensor 105 is active, for example while the phone 100 in an in-call state, any detection of a near event can cause the screen 101 to be switched off. By in-call it is meant that the phone 100 is in an ongoing call, incoming or outgoing. While the phone 100 is in an in-call state, and the user tries to interact with the device 100 such that a part his/her hand or finger 108 comes within the FoV of the proximity sensor 105, a near event may be detected even though it is not desired, or even required. In certain devices, performing a pull-down swipe, for example to view notifications, may almost be impossible to execute while the device is in a certain state, such as an in-call state. For example, in FIG. 1, if the phone 100 were in an in-call state, the user could be hindered from properly interacting with the device if during the interaction, the fingertip 108 came within the FoV of the proximity sensor 105. Such interaction could be a pull-down swipe as previously explained, i.e., swiping the fingertip 108 on the screen 101 from the top-edge 110 in the direction 130. Especially near the top-edge 110, a part of the finger 180 may trigger a detection of a near event by the proximity sensor 105. The detection of the near event will then result in the screen 101 being switched off. In such a case, the screen turns off not because the phone is being held near the ear or the user's head, but because there is a finger nearby. It has been observed by the applicant that in certain smartphones, a pull-down swipe from the top edge of the screen during an ongoing phone call can be very hard to perform because when attempting to perform a pull-down swipe, presence of the user's finger or hand is detected as a near event which switches off the touchscreen and/or the display.

It can further be observed that the detection of a near event resulting in the screen 101 being switched off can also exist in a hands-free mode. By saying hand-free mode it will be understood that the user is not resting the earpiece 120 against or near his/her ear. In a hands-free call, either the same speaker as the one inside the earpiece 120 is being driven at a larger volume, or the device may have another dedicated hands-free speaker. Whether the phone is in-call in hands-free mode or otherwise, or the call is a call through a mobile network, such as GSM or CDMA, or whether the call is a VOIP call, the problem of an undesired screen-off may exist in any of such modes or use cases. Accordingly, the present teachings are not limited to any specific use case or configuration.

In this disclosure, by saying that the proximity sensor 105 is active, it is meant that a presence of an object within a certain region around the sensor 105 results in a detection of a certain event in the proximity sensing system. When saying that the proximity sensor is inactive it is meant that the presence of an object within a certain region around the sensor 105 does not result in a detection of the certain event in the proximity sensing system, irrespective of whether the sensor 105 itself is disabled or powered off or just the output of the sensor is being ignored by a processing system. Furthermore, when active, in addition to the presence of an object, the proximity sensing system may also detect the absence or removal of an object, which was previously detected within a certain region around the sensor 105. The detection of absence or removal of the object may generate another event in the proximity sensing system. Similarly, when inactive, it is meant that the absence of the object does not result in a detection of the another event in the proximity sensing system, irrespective of whether the sensor 105 itself is disabled or powered off or just the output of the sensor is being ignored by the processing system. The events resulting in the proximity sensing system from the presence and absence of one or more objects can be called near and far events, respectively. Near and far events can generate near detection signal and far detection signal respectively. In addition to just detecting the presence, the proximity sensing system may detect movement of the object approaching towards the sensor 105 to issue the near detection signal. Similarly, in addition to just detecting the absence, the proximity sensing system may detect movement of the object departing away from the sensor 105 to issue the far detection signal.

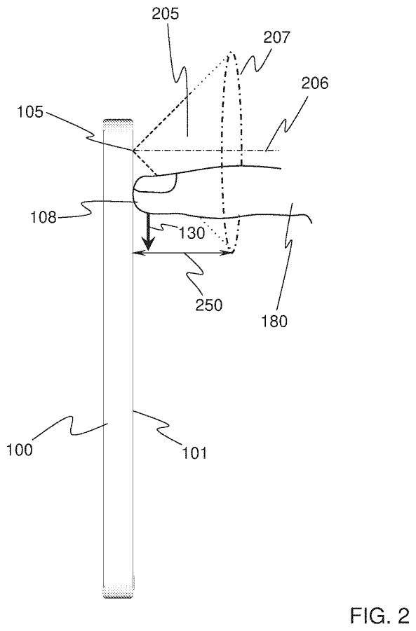

FIG. 2 shows a perspective side-view of the phone 100. The FoV 205 of the proximity sensing system is shown extending in a divergent manner from the proximity sensor 105 along an axis 206 such that the cross-sectional area of the FoV 205 in a plane normal to the axis 206 increases with distance from the proximity sensor 105 along the axis 206. Usually the FoV 205 will extend to a certain distance 250 from the sensor 105. Accordingly, FoV 205 is the region or 3D space within which the proximity sensing system can reliably detect the proximity of an object. In this example, the FoV 205 is shown as a conical shape with its vertex at the location of the proximity sensor 105 and the base 207 of the cone representing the limit within which a reliable sensing is possible. Alternatively, the base 207 of the cone could represent the limit within which proximity sensing is desired. The conical shape of the FoV 205 is shown just as an example. In some cases, the FoV 205 may be asymmetrical in either or all directions and may have another shape depending upon the sensor used. For example, an ultrasound-based proximity sensor usually has a wider FoV than an IR based proximity sensor. As a skilled person will recognize, a certain shape of the FoV is not limiting to the generality of the present teachings.

FIG. 2 further shows the user interacting with the device 100 using his/her fingertip 108. A part of the finger 180 is lying within the FoV 205 such that a near event will be detected in certain situations, such as the phone 100 being in an in-call condition. Accordingly, detection of a near event may prevent an execution of a pull-down swipe 130 during an in-call condition.

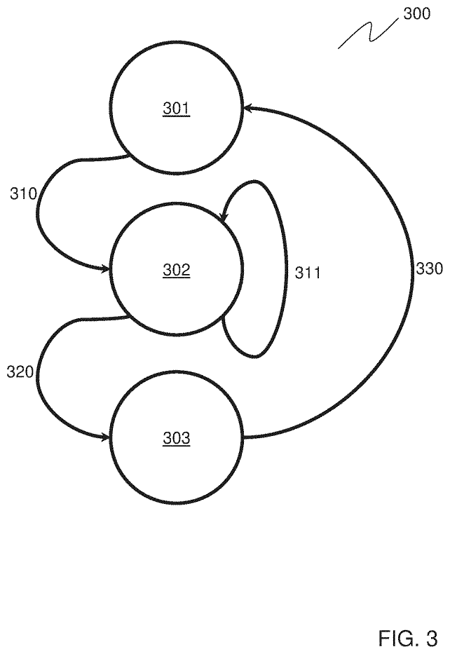

FIG. 3 shows a state-diagram 300 illustrating a conventional method for control of screen of an electronic device such as a smartphone. The electronic device can be the device 100 that is shown in the previous figures. The state-diagram 300 shows the behavior of the electronic device in conditions where proximity sensing is enabled. An example of such condition is an in-call situation. State 301 represents a state when the screen is on. Here, the term screen may include the touchscreen and/or the backlight for the screen. In the state 301 at least the touchscreen is on. When a near event 310 is detected by the proximity sensing system, the device enters a near state 302. While the device is the near state 302, any touch event 311 that occurs in this state 302 does not result in a change in the state. In other words, any touch event 311 occurring while the device is in the near state 302 is ignored by the device. The touch event 311 can be any interaction, intentional or unintentional, that occurs through the touchscreen of the device. An unintentional interaction can, for example, be a contact between the ear of the user and the screen. An intentional interaction can, for example, be a pull-down swipe or any other purposeful touch or tap on the screen of the device. As will be appreciated, the pull-down swipe will also be ignored if the device is in a near state. As was explained previously, the near state 302 can be triggered by an object being in the FoV 205 of the proximity sensing system of the device.

When the device enters the near state 302 triggered by a near event, a timeout timer can be triggered that waits for a time-period of predetermined length, upon expiry of which period the screen is switched off. The time-period can be counted up or down, accordingly the timer can be a count-up or count-down timer respectively. The expiry of the time-period can be termed a timeout event 320 or more simply timeout. When the timeout event 320 occurs, the screen is switched off. By saying that the screen is switched off, here it is meant that at least the touchscreen sensing or the touchscreen is disabled, switched off. In addition, the screen backlight and the screen driver can also be disabled.

Furthermore, it will be appreciated that the screen backlight and the screen driver may also be disabled while the device is in the near state 302 while the touchscreen sensing is still kept active. This can allow touch events to be detected for a longer period of time, while still saving power.

By using the term disabled, various alternative conditions such as switched off, powered off, entering a low power state, sensor outputs being disabled, are all included as possible additions or alternatives for switching off the screen of the device. Consequently, upon timeout 320, the device enters a screen switched-off state 303. As will be appreciated, in the screen switched-off state 303, the touchscreen and preferably also the display of the device are disabled such that no touch-based interaction is possible with the device.

In the screen switched-off state 303, the device can be woken up by a detection 330 of a far event. The far event 330 can simply be a condition which is equivalent to the removal of the near event 302 that caused the screen to the switched-off, or alternatively there may be a hysteresis between the distance between an object approaching the proximity sensor and the proximity sensor that triggers a near event when the distance becomes lower than a certain value, and the distance between the same object and the proximity sensor which causes the far event when the object moves beyond a certain distance from the proximity sensor. When the far event 330 is detected, the device goes back to the screen on state 301.

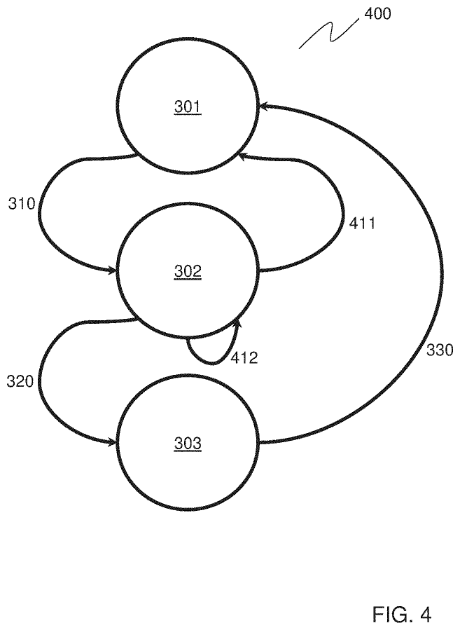

FIG. 4 shows a modified state-diagram 400 showing a method according to the present teachings. In the modified method, the device changes from the screen on state 301 to the near state 302 when a near event 310 is detected. When timeout 320 occurs, the device changes to a screen-off state 303. While in the screen off state 303, occurrence of a far event 330 results in the device returning to the screen-on state 301. These states are events were discussed in detail in context of FIG. 3 and apply to FIG. 4 as well. Instead of ignoring the occurrence any touch event 311 as in FIG. 3, in the modified method, the touch events are divided in at least two categories.

In FIG. 4, touch events 411 and 412 belonging to two such categories are shown. The touch events may be divided in categories, for example, based upon the location where they occur on the screen. Alternatively, or in combination, the touch events may be divided in categories based upon a type of the touch event.

As an example, the touch events occurring on the bottom half of the screen can lie in a second category 412 of touch events, whereas the touch events occurring on the top half of the screen can lie in a first category 411 of the touch events. The top half will be understood as the portion of the screen area spanning between the top-edge 110 and until a given distance essentially in the middle of the screen 101. The bottom half is the remaining portion of the screen 101. The skilled person will understand that terms top and bottom are used in a relative sense and do not limit the present teachings to a given division of the screen area, symmetrical or asymmetrical. Moreover, the categories of touch events may be more than two. As will be appreciated, instead of the first half and second half, the screen may be divided in a first portion and second portion respectively. The first portion may be smaller than the second portion or vice versa.

As a further example, the touch events may be divided in categories based on the type of the touch event. Accordingly, the touch event may be evaluated to determine if the touch event is of a first type, such as a tap, hold or swipe and deemed to be a first category touch event. Since such types of events are unlikely to be caused unintentionally, i.e., by contact of the phone with the user's ear or cheek, such events may be accepted or not ignored. It will be appreciated that other types of touch events, or second type of touch events that cannot be distinguished from an undesired touch event such as from unintentional contact with the user's ear or cheek can be ignored.

While the device is the near state 302, any second category touch event 412, i.e., a touch event occurring at the bottom portion of the screen and/or the second type of touch event, does not result in a change in the state. In other words, any second category touch event 412 occurring while the device is in the near state 302 is ignored by the device. According to an aspect the second category touch event 412 can be any interaction, intentional or unintentional, that occurs through the bottom portion of the touchscreen. Alternatively, or in addition, the second category touch event 412 is a specific type of touch event occurring on the screen, or the second type of touch event as discussed previously.

In addition, while the device is the near state 302, any first category touch event 411, i.e., a touch event occurring at the top portion of the screen and/or a first type of touch event, results in the device from changing to the screen-on state 301. In other words, any first category touch event 411 occurring while the device is in the near state 302 will switch-on the screen of the device. The first category touch event 411 can be any interaction, intentional or unintentional, that occurs through the top portion of the touchscreen. Alternatively, first category touch event 411 can be the first type of touch event occurring anywhere on the screen.

According to an aspect, before changing from the near state 302 to the screen-on state 301 after detecting the first category touch event 411, the method comprises a step of verifying that the first category touch event 411 is an intentional touch event. The first category touch event 411 can be identified as an intentional event, for example, by comparing the occurred first category touch event 411 is a predetermined type of touch event, such as a tap, double-tap, hold, or a swipe. More specifically the swipe can be a pull-down swipe. If the first category touch event 411 cannot be recognized as an intentional touch event, the system enters the screen-off state 303 at timeout 320.

As will be appreciated, according to an aspect the present teachings can provide an increased flexibility in setting the timeout 320 time-duration as touch events can now be filtered firstly based on the location where they occur on the screen, and optionally secondly, by estimating whether the touch event is intentional or unintentional.

It can be advantageous to adapt the timeout duration according to the use case of the device. For example, if an on-table movement detected by processing one or more signals from the proximity sensor, and/or one or more signals from other sensors or modules in the electronic device, the timeout duration may be increased to allow more time for the user to interact with the device. In a hands-free call scenario, the user may decide to rest the phone on a table or such surface such that he is not required to hold the phone while being in the call. In such a case, the chances of false touch events can be significantly low as compared to a call where the user is resting the earpiece close to or against his/her ear. Thus, in hands-free cases, according to the present teachings, a larger timeout duration may be allowed if certain conditions are detected, such as a movement to place the device on a table or such object. Similarly, for other use cases, the modified method may adapt the timeout duration such that the user experience is improved.

According to another aspect, the method may utilize machine learning and artificial intelligence (“AI”) for recognizing and further improving the determination of the use case and subsequent adapting of the timeout period such that the user may interact with the device with minimum number of interruptions due to screen-off, while at the same time maximizing rejection of false touch events.

Alternatively, or in combination, before changing from the near state 302 to the screen-on state 301 after detecting the first category touch event 411, the method also comprises a step of checking that active notifications exist. By active notifications it is meant that the user has not cleared the notification area such that at least one notification exists. Accordingly, if no notification exists, or the notification area is empty, the first category touch event 411 does not change the device to a screen-on state 301. In such a case, both touch events 411 and 412 are ignored. Similarly, if at least one notification exists in the notification area, or the notification area is not empty, the occurrence of the first category touch event 411 changes the device to the screen-on state 301.

It will be appreciated that the notifications area may be defined as a set of coordinates e.g., a dedicated area on the screen, a type of gesture such as a swipe, or a combination of both.

Various embodiments have been described above for a method for controlling an electronic device, and for such an electronic device comprising a touch-sensitive surface. Those skilled in the art will understand, however that changes and modifications may be made to those examples without departing from the spirit and scope of the following claims and their equivalents. It will further be appreciated that aspects from the method and product embodiments discussed herein may be freely combined.

Certain embodiments are summarized in the following clauses.

Clause 1.

A method for controlling an electronic device comprising a touch-sensitive surface and a proximity sensor, the method comprising the steps of:
Changing the device from a screen-on state to a near state in response to a near event being detected by the proximity sensor, wherein the screen-on state is a state in which user inputs are accepted through the touch-sensitive surface; and the near event occurs when an input object is determined to be in proximity of the electronic device by the proximity sensor;
While the device is in the near state, processing a first category touch event, and in response to the processing of the first category touch event, performing at least one function on the electronic device;
While the device is in the near state, ignoring a second category touch event, wherein the second category touch event is distinct from the first category touch event.

Clause 2.

The method according to clause 1, wherein the first category touch event includes touch input occurring within a first portion of the touch-sensitive surface and the second category touch event includes touch input occurring in a second portion of the touch-sensitive surface, the first portion and the second portion being non-overlapping portions of the touch-sensitive surface.

Clause 3.

The method according to any of the above clauses, wherein the first category touch event is a first type of touch event and the second category touch event is a second type of touch event distinct from the first type of touch event.

Clause 4.

The method according to clause 3, wherein the first type touch event is any one or more of, tap, hold, or swipe.

Clause 5.

The method according to any of above clauses, wherein the electronic device comprises a display.

Clause 6.

The method according to clause 5, wherein the display remains on while the electronic device is in the near state.

Clause 7.

The method according to clause 6, wherein the display remains on for a predetermined time-period after the electronic device changes to the near state.

Clause 8.

The method according to clause 6, wherein the display is turned off when the electronic device changes to the near state.

Clause 9.

The method according to any of above clauses, further including the steps of:
Waiting for a predetermined time-period in the near state within which period, if no first category touch event is detected, changing the device to a screen-off state, wherein the screen-off state is a state in which the touch-sensitive surface is either disabled or any inputs received thereof are ignored; and
Changing from the screen-off state to the screen-on state in response to a far event being detected by the proximity sensor, wherein the far event occurs when the input object is determined to no longer be in proximity of the electronic device by the proximity sensor.

Clause 10.

The method according to any of the above clauses, wherein the proximity sensor is based on infrared (“IR”) detection.

Clause 11.

The method according to any of the above clauses 1-10, wherein the input object is determined to be in proximity of the electronic device when the input object, relative to the electronic device, arrives within a first predetermined distance of the proximity sensor.

Clause 12.

The method according to any of the above clauses 9-11, wherein the input object is determined to no longer be in proximity of the electronic device when the electronic device, relative to the electronic device, moves beyond a second predetermined distance from the proximity sensor.

Clause 13.

The method according to any of the above clauses 1-9, wherein said proximity sensor is based on acoustic detection.

Clause 14.

The method according to any of the above clauses 1-9, wherein said proximity sensor is based on capacitive detection.

Clause 15.

The method according to any of the above clauses 9-14, wherein the magnitude of the first predetermined distance is at least substantially equal to the magnitude of the second predetermined distance.

Clause 16.

The method according to any of the above clauses 9-14, wherein the magnitude of the first predetermined distance is different from the magnitude of the second predetermined distance.

Clause 17.

An electronic device comprising a touch-sensitive surface and a proximity sensor, the electronic device also comprising a processing unit configured to:
process user input received through the touch-sensitive surface;
process signal received by the proximity sensor, wherein
   the electronic device is configured to enter a near state in response to a near event being detected by the proximity sensor; and the screen-on state being a state in which user inputs are accepted through the touch-sensitive surface and processed by the processing unit; and the near event occurs when an input object is determined to be in proximity of the electronic device by the proximity sensor;
process a first category touch event, and based on the processing of the first category touch event performing at least one function on the electronic device; and
ignore a second category touch event, wherein the second category touch event is distinct from the first category touch event.

Clause 18.

The electronic device according to clause 17, wherein the first category touch event includes touch input occurring within a first portion of the touch-sensitive surface and the second category touch event includes touch input occurring in a second portion of the touch-sensitive surface, the first portion and the second portion being non-overlapping portions of the touch-sensitive surface.

Clause 19.

The electronic device according to any of the above clauses 17-18, wherein the first category touch event is a first type of touch event and the second category touch event is a second type of touch event.

Clause 20.

The electronic device according to clause 19, wherein the first type touch event is any one or more of, tap, hold, or swipe.

Clause 21.

The electronic device according to clause 18, wherein the processing unit is configured to ignore the second category touch event by disabling the second portion of the touch-sensitive surface.

Clause 22.

The electronic device according to clause 18, wherein the processing unit is configured to ignore the second category touch event by disregarding touch inputs received through the second portion of the touch-sensitive surface.

Clause 23.

The electronic device according to any of the clauses 17-22, wherein the proximity sensor is based on Infrared (“IR”) detection.

Clause 24.

The electronic device according to any of the clauses 17-22, wherein the proximity sensor is based on acoustic detection.

Clause 25.

A computer software product having specific capabilities for executing the steps any of the clauses 1-16.

Clause 26.

An electronic device configured to execute the steps any of the clauses 1-16.

1. A method for controlling an electronic device comprising a touch-sensitive surface and a proximity sensor, the method comprising:
charging the device from a screen-on state to a near state in response to a near event being detected by the proximity sensor, wherein the screen-on state is a state in which user inputs are accepted through the touch-sensitive surface; and the near event occurs when an input object is determined to be in proximity of the electronic device by the proximity sensor;
while the device is in the near state, processing a first category touch event, and in response to the processing of the first category touch event, performing at least one function on the electronic device; and
while the device is in the near state, ignoring a second category touch event, wherein the second category touch event is distinct from the first category touch event.

2. The method according to claim 1, wherein the first category touch event includes touch input occurring within a first portion of the touch-sensitive surface and the second category touch event includes touch input occurring in a second portion of the touch-sensitive surface, the first portion and the second portion being non-overlapping portions of the touch-sensitive surface.

3. The method according to claim 1, wherein the first category touch event is a first type of touch event and the second category touch event is a second type of touch event distinct from the first type of touch event.

4. The method according to claim 3, wherein the first type touch event is any one or more of, tap, hold, or swipe.

5. The method according to claim 1, wherein the electronic device comprises a display.

6. The method according to claim 5, wherein the display remains on while the electronic device is in the near state.

7. The method according to claim 6, wherein the display remains on for a predetermined time-period after the electronic device changes to the near state.

8. The method according to claim 6, wherein the display is turned off when the electronic device changes to the near state.

9. The method according to claim 1, comprising:
waiting for a predetermined time-period in the near state within which period, if no first category touch event is detected, changing the device to a screen-off state, wherein the screen-off state is a state in which the touch-sensitive surface is either disabled or any inputs received thereof are ignored; and
changing from the screen-off state to the screen-on state in response to a far event being detected by the proximity sensor, wherein the far event occurs when the input object is determined to no longer be in proximity of the electronic device by the proximity sensor.

10. The method according to claim 1, wherein the proximity sensor is based on infrared (“IR”) detection.

11. The method according to claim 1, wherein the input object is determined to be in proximity of the electronic device when the input object, relative to the electronic device, arrives within a first predetermined distance of the proximity sensor.

12. The method according to claim 9, wherein the input object is determined to no longer be in proximity of the electronic device when the electronic device, relative to the electronic device, moves beyond a second predetermined distance from the proximity sensor.

13. The method according to claim 1, wherein the proximity sensor is based on acoustic detection.

14. The method according to claim 1, wherein the proximity sensor is based on capacitive detection.

15. The method according to claim 9, wherein the magnitude of the first predetermined distance is at least substantially equal to the magnitude of the second predetermined distance.

16. The method according to claim 9, wherein the magnitude of the first predetermined distance is different from the magnitude of the second predetermined distance.

17. An electronic device comprising a touch-sensitive surface and a proximity sensor, the electronic device also comprising a processing unit configured to:
process user input received through the touch-sensitive surface;
process signal received by the proximity sensor, wherein
the electronic device is configured to enter a near state in response to a near event being detected by the proximity sensor; and the screen-on state being a state in which user inputs are accepted through the touch-sensitive surface and processed by the processing unit; and the near event occurs when an input object is determined to be in proximity of the electronic device by the proximity sensor;
process a first category touch event, and based on the processing of the first category touch event performing at least one function on the electronic device; and
ignore a second category touch event, wherein the second category touch event is distinct from the first category touch event.

18. The electronic device according to claim 17, wherein the first category touch event includes touch input occurring within a first portion of the touch-sensitive surface and the second category touch event includes touch input occurring in a second portion of the touch-sensitive surface, the first portion and the second portion being non-overlapping portions of the touch-sensitive surface.

19. The electronic device according to claim 17, wherein the first category touch event is a first type of touch event and the second category touch event is a second type of touch event.

20. The electronic device according to claim 19, wherein the first type touch event is any one or more of, tap, hold, or swipe.

21. The electronic device according to claim 18, wherein the processing unit is configured to ignore the second category touch event by disabling the second portion of the touch-sensitive surface.

22. The electronic device according to claim 18, wherein the processing unit is configured to ignore the second category touch event by disregarding touch inputs received through the second portion of the touch-sensitive surface.

23. The electronic device according to claim 17, wherein the proximity sensor is based on Infrared (“IR”) detection.

24. The electronic device according to claim 17, wherein the proximity sensor is based on acoustic detection.

25. A computer software product having specific capabilities for executing the steps any of claim 1.
